(19) United States
(12) Patent Application Publication
(10) Pub. No.: US 2012/0222715 A1
(43) Pub. Date: Sep. 6, 2012

(54) Railbox car and highway vehicle "use" of solar panels owned by others

(76) Inventor: Robert D. Morse, Moorestown, NJ (US)

(21) Appl. No.: 12/806,678

(22) Filed: Mar. 3, 2011

(51) Int. Cl. H01L 31/042

(52) U.S. Cl. 136/244

(57) ABSTRACT

My patent covers the use of solar panels on the tops and sides of freight trains or trucks, owned and installed by others, that may benefit from the production of electric power they generate for whatever purpose.

The panels may be applied in rows or otherwise allowing walking space on all roofs of the vehicles in whatever manner best suited.

Storage or collecting cells may be carried in selected fright cars with couplings, automatic or manual, and in a selected area of a truck or train.

### REFERENCE TO DRAWINGS

FIG. 1, A: installation of solar panels located on the sides of trucks of the benefit of production of electric power they generate, for whatever purpose. Panels may be installed in rows or otherwise.

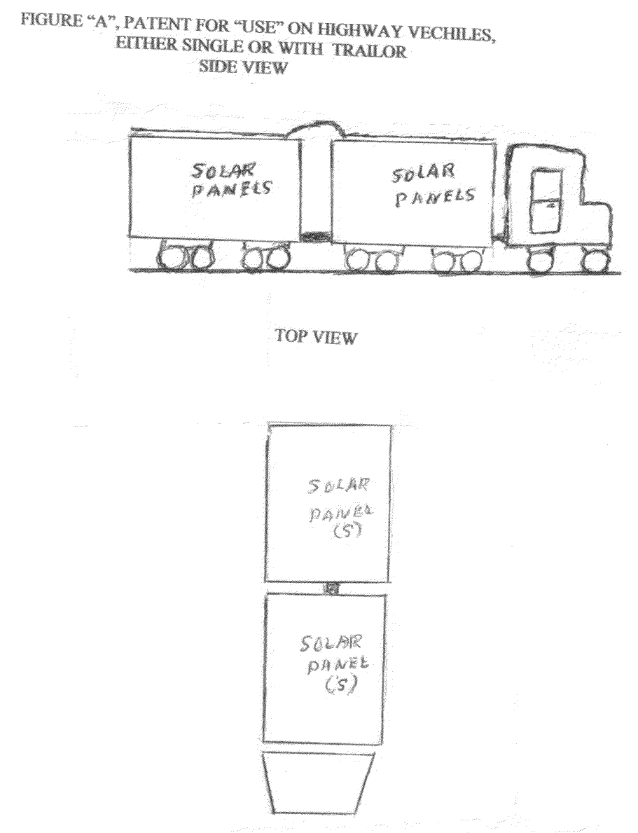

FIG. 1, B: installation of solar panels located on the tops of trucks of the benefit of production of electric power they generate, for whatever purpose. Panels may be installed in rows, allowing walking space on the roof of vehicle, in whatever manner is best suited.

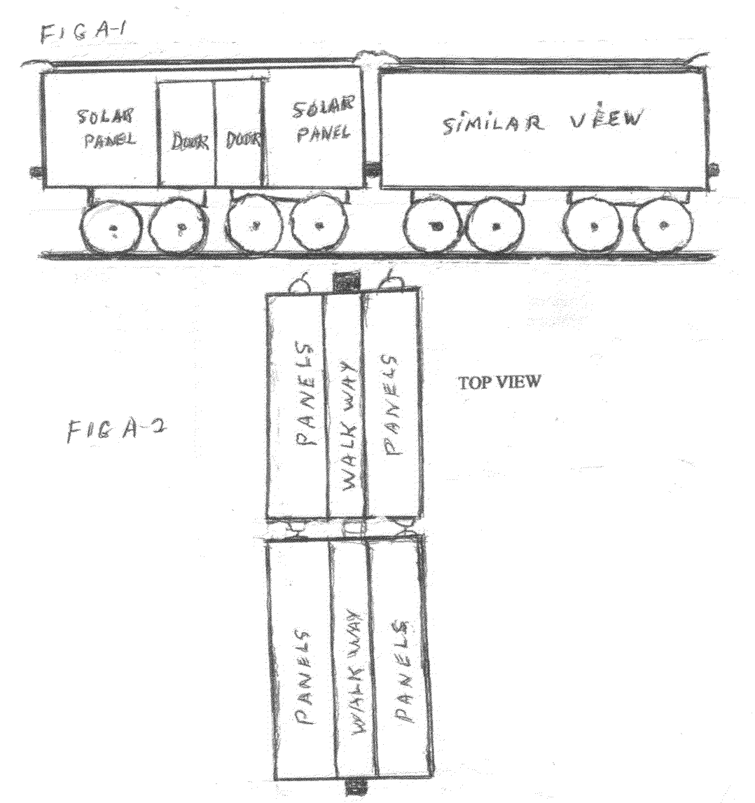

### BRIEF SUMMARY OF INVENTION

My patent cover the use of solar panels on trucks for the purpose of collecting and/or using energy. The location of the solar panels on the trucks can be owned and installed by others for electric power they generate for whatever purpose.

1. I claim the drawings and idea for use of Solar Panels on Trucks and Trains, owned and installed by others, is a “Use” invention of my own.
